(19) United States
(12) Patent Application Publication
(10) Pub. No.: US 2026/0150624 A1
(43) Pub. Date: May 28, 2026

(54) WAFER CHUCK WITH MULTI-ZONE THERMAL CONTROL

(71) Applicant: Mikros Technologies LLC, Claremont, NH (US)

(72) Inventors: Joseph T. Sullivan, Hanover, NH (US); Jesse D. McGowan, Alexandria, NH (US); Drew M. Matter, Hanover, NH (US)

(73) Assignee: Mikros Technologies LLC, Claremont, NH (US)

(21) Appl. No.: 19/289,570

(22) Filed: Aug. 4, 2025

Related U.S. Application Data
(60) Provisional application No. 63/725,375, filed on Nov. 26, 2024.

(51) Int. Cl. H10P 72/78

(52) U.S. Cl. CPC H10P 72/78

(57) ABSTRACT

A chuck assembly that includes a manifold base defining one or more channels therein and cold plates coupled to the manifold base and configured to support a wafer. The manifold base includes inlet ports in fluid communication with the one or more channels and outlet ports in fluid communication with the one or more channels. Each cold plate defines a cold plate channel that is in fluid communication with the one or more channels of the manifold base. Additionally, a fluid is configured to enter the one or more channels of the manifold base through the inlet ports, selectively flow through at least a portion of the cold plate channels to locally thermally regulate a region of the wafer, and exit the one or more channels of the manifold base through the outlet ports.

### CROSS REFERENCE TO RELATED APPLICATION(S)

The present application claims priority to and the benefit of U.S. Provisional Patent Application Serial No. 63/725,375, filed November 26, 2024, the contents of which are herein incorporated by reference as if set forth herein in its entirety.

### TECHNICAL FIELD

This disclosure relates to a semiconductor wafer chuck, and more particularly, to a thermally regulated wafer chuck that includes multiple thermally regulated zones.

### BACKGROUND

Wafer chucks are essential components in semiconductor manufacturing processes. The wafer chucks may provide a stable platform for holding semiconductor wafers during various processing steps, such as lithography, etching, deposition, and component testing. Temperature control of the wafer disposed on the wafer chuck may be critical during these processes to ensure uniform processing conditions and/or to prevent defects.

Wafer chucks may frequently include a planar surface that supports the wafer during the aforementioned processing steps. The wafer may be secured to the wafer chuck using a vacuum (e.g., using suction) to hold the wafer in place. Additionally, to maintain a temperature of the wafer during manufacturing and/or testing (e.g., probing), a coolant (e.g., a coolant fluid) may be circulated through all or a portion of the wafer chuck, thereby acting as a heat exchanger to actively cool the wafer.

### SUMMARY

In one implementation, a chuck assembly is disclosed. The chuck assembly includes a manifold base defining one or more channels therein and cold plates coupled to the manifold base and configured to support a wafer. The manifold base includes inlet ports in fluid communication with the one or more channels and outlet ports in fluid communication with the one or more channels. Each cold plate defines a cold plate channel that is in fluid communication with the one or more channels of the manifold base. Additionally, a fluid is configured to enter the one or more channels of the manifold base through the inlet ports, selectively flow through at least a portion of the cold plate channels to locally thermally regulate a region of the wafer, and exit the one or more channels of the manifold base through the outlet ports.

In some implementations, the inlet ports may be configured to selectively regulate the fluid from entering the one or more channels of the manifold base through the inlet ports and the outlet ports may be configured to selectively regulate the fluid from exiting the one or more channels of the manifold base through the outlet ports such that the fluid selectively flows through at least the portion of the cold plate channels to locally thermally regulate the region of the wafer. Each of the inlet ports may include or may be in fluid communication with a respective inlet valve that regulates the fluid from entering the one or more channels of the manifold base through the inlet ports. Each of the outlet ports may include or may be in fluid communication with a respective outlet valve that regulates the fluid from exiting the one or more channels of the manifold base through the outlet ports.

In some implementations, the manifold base may further define a cutout. The cold plates may be positioned within the cutout. Each of the cold plates may define a top surface that is configured to contact and support the wafer. The top surfaces of the cold plates may be substantially coplanar.

In some implementations, each of the cold plates may include a top layer that is configured to support the wafer, a bottom layer, and an intermediate layer disposed between the top layer and the bottom layer. The intermediate layer may be configured to heat the top layer, the bottom layer, or both.

In some implementations, each of the cold plates may include a cold plate inlet and a cold plate outlet. The fluid may be configured to enter the cold plate channel through the cold plate inlet and exit the cold plate channel through the cold plate outlet. The cold plate inlet may be received by a first opening defined by the manifold base and the cold plate outlet may be received by a second opening defined by the manifold base such that the fluid may flow from the one or more channels of the manifold base, into the cold plate channel, and exit the cold plate channel to reenter the one or more channels of the manifold base.

In some implementations, the manifold base may further include a vacuum port. Additionally, the cold plates may be spaced apart to form gaps therebetween, and the gaps may be in fluid communication with the vacuum port. The wafer may be configured to be suctioned to the cold plates by establishing an air flow path from the gaps towards the vacuum port.

In another implementation, a chuck assembly is disclosed. The chuck assembly includes a manifold base and a cold plate disposed on the manifold base. The manifold base includes an inlet port and an outlet port. The cold plate is in fluid communication with the manifold base and configured to support a wafer disposed on a top surface of the cold plate. The cold plate includes a top layer that includes the top surface of the cold plate, a bottom layer that couples the cold plate to the manifold base and establishes fluid communication between the manifold base and the cold plate, and an intermediate layer disposed between the top layer and the bottom layer. A fluid is configured to thermally regulate the wafer, and the fluid is configured to enter the manifold base through the inlet port, flow through the cold plate, reentering the manifold base, and exit the manifold base through the outlet port.

In some implementations, the cold plate may define a cold plate channel and the manifold base may define a channel. The cold plate channel may be in fluid communication with the channel of the manifold base. The cold plate channel may extend through at least one of the top layer, the bottom layer, or the intermediate layer. The cold plate may include a cold plate inlet that is in fluid communication with the cold plate channel and a cold plate outlet that is in fluid communication with the cold plate channel. The cold plate inlet and the cold plate outlet are received by respective openings defined by the manifold base to establish fluid communication between the manifold base and the cold plate. The cold plate inlet and the cold plate outlet may project from the bottom layer.

In some implementations, the intermediate layer may be configured to heat the top layer, the bottom layer, or both.

In some implementations, the top surface of the cold plate may be coplanar with a top surface of the manifold base.

In some implementations, the inlet port may include an inlet valve that is configured to regulate the fluid entering the manifold base through the inlet port and the outlet port may include an outlet valve that is configured to regulate the fluid exiting the manifold base through the outlet port.

In another implementation, a chuck assembly is disclosed. The chuck assembly includes a manifold base defining one or more channels therein and cold plates disposed in a cutout defined by the manifold base to form a support surface of the chuck assembly that is configured to support a wafer. The manifold base includes inlet ports that are configured to regulate a fluid entering the channels of the manifold base, and outlet ports that are configured to regulate a fluid exiting the channels of the manifold base. The cold plates are selectively in fluid communication with the manifold base based upon regulation of the fluid by the inlet ports, the outlet ports, or both to locally thermally regulate a region of the wafer.

### BRIEF DESCRIPTION OF THE DRAWINGS

The disclosure is best understood from the following detailed description when read in conjunction with the accompanying drawings. It is emphasized that, according to common practice, the various features of the drawings are not to scale. On the contrary, the dimensions of the various features are arbitrarily expanded or reduced for clarity.

FIG. 1 is a cross-sectional view of a chuck supporting a wafer.

FIG. 2 is a top-down view of the wafer shown in FIG. 1 that illustrates directions of expansion and contraction of the wafer.

FIG. 3 is a top-down view of another example of a wafer that illustrates directions of expansion and contraction of the wafer.

FIG. 4A is a perspective view of a chuck assembly in accordance with the present teachings.

FIG. 4B is an exploded perspective view of the chuck assembly shown in FIG. 4A.

FIG. 5 is a perspective view of a cold plate of the chuck assembly shown in FIGS. 4A and 4B.

FIG. 6 is a cross-sectional view of the cold plate shown in FIG. 5.

FIG. 7A is a schematic view of the chuck assembly that illustrates flow paths of a fluid through the chuck assembly.

FIG. 7B is another schematic view of the chuck assembly shown in FIG. 7A, illustrating a second example of a flow path through the chuck assembly.

### DETAILED DESCRIPTION

Reference will now be made in greater detail to embodiments, examples of which are illustrated in the accompanying drawings. Wherever possible, the same reference numerals will be used throughout the drawings and the description to refer to the same or like parts.

As used herein, the terminology “determine” and “identify,” or any variations thereof includes selecting, ascertaining, computing, looking up, receiving, determining, establishing, obtaining, or otherwise identifying or determining in any manner whatsoever using one or more of the devices and methods are shown and described herein.

As used herein, the terminology “example,” “the embodiment,” “implementation,” “aspect,” “feature,” or “element” indicates serving as an example, instance, or illustration. Unless expressly indicated, any example, embodiment, implementation, aspect, feature, or element is independent of each other example, embodiment, implementation, aspect, feature, or element and may be used in combination with any other example, embodiment, implementation, aspect, feature, or element.

As used herein, the terminology “or” is intended to mean an inclusive “or” rather than an exclusive “or.” That is, unless specified otherwise, or clear from context, “X includes A or B” is intended to indicate any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from the context to be directed to a singular form.

As used herein, unless explicitly stated otherwise, any term specified in the singular may include its plural version. For example, “a computer that stores data and runs software,” may include a single computer that stores data and runs software or two computers – a first computer that stores data and a second computer that runs software. Also “a computer that stores data and runs software,” may include multiple computers that together stored data and run software. At least one of the multiple computers stores data, and at least one of the multiple computers runs software.

As used herein, unless explicitly stated otherwise, the term fluid and/or coolant fluid may refer to, but is not limited to, electronics coolant liquids containing perfluorinated compounds (PFCs), water, and/or water-glycol mixes (brines).

Further, for simplicity of explanation, although the figures and descriptions herein may include sequences or series of steps or stages, elements of the methods disclosed herein may occur in various orders or concurrently. Additionally, elements of the methods disclosed herein may occur with other elements not explicitly presented and described herein. Furthermore, not all elements of the methods described herein may be required to implement a method in accordance with this disclosure and claims. Although aspects, features, and elements are described herein in particular combinations, each aspect, feature, or element may be used independently or in various combinations with or without other aspects, features, and elements.

Further, the figures and descriptions provided herein may be simplified to illustrate aspects of the described embodiments that are relevant for a clear understanding of the herein disclosed processes, machines, and/or manufactures, while eliminating for the purpose of clarity other aspects that may be found in typical similar devices, systems, and methods. Those of ordinary skill may thus recognize that other elements and/or steps may be desirable or necessary to implement the devices, systems, and methods described herein. However, because such elements and steps do not facilitate a better understanding of the disclosed embodiments, a discussion of such elements and steps may not be provided herein. However, the present disclosure is deemed to inherently include all such elements, variations, and modifications to the described aspects that would be known to those of ordinary skill in the pertinent art in light of the discussion herein.

Described herein is a chuck assembly that is configured to support and/or secure a semiconductor wafer (herein referred to as a “wafer”). The chuck assembly may be configured to support and/or secure the wafer during manufacturing and/or testing of the wafer. By way of example, the chuck assembly may be configured to support and secure the wafer during probing of the wafer, whereby a probe may test the wafer to ensure proper functionality and quality. Additionally, the chuck assembly may be configured to thermally regulate the wafer during manufacturing and/or testing. The chuck assembly may thermally regulate (e.g., heat and/or cool) all or a portion of the wafer to maintain the structural integrity of the wafer. By way of example, the chuck assembly may be configured to locally thermally regulate one or more regions (e.g., portions) of the wafer based on a particular manufacturing process or testing process.

In the semiconductor industry, wafers, such as silicon wafers or other semiconductor substrates, may undergo rigorous testing to ensure their functionality and quality. During testing, these wafers may typically be held in place by a chuck to secure the wafer when probing occurs. That is, the chuck may provide a stable platform for the wafer while allowing precise positioning of a probe (e.g., precise positioning of electronic contacts of the probe) with respect to the wafer. Additionally, due to temperature fluctuations of the wafer caused by testing, the chuck may include a coolant system or other means to help thermally regulate the wafer. For example, conventional chucks may often be generally cooled by a fluid (i.e., a coolant fluid) or increased air circulation in an attempt to mitigate temperature fluctuations of the wafer.

However, as microprocessor capabilities continue to improve and increase in performance, there remains a need to better thermally regulate wafers during manufacturing and/or testing. For example, as wafers become more advanced due to improved microprocessor capabilities, the testing required for such wafers will become even more demanding and more rigorous. As a result, the testing (e.g., probing) may itself generate localized regions of increased heat within the wafer, which may cause unwanted damage to the wafer, inaccurate measurements during testing, probe misalignment, or a combination thereof, thereby resulting in increased manufacturing costs.

By way of example, the wafer may be probed during testing, which may result in only a portion of the wafer that is being tested generating localized heat. That is, the portion of the wafer being testing may exhibit significantly heightened temperatures when compared to a surrounding region of the wafer (e.g., a hot region of the wafer being surrounding by a cold region of the wafer). Such temperature fluctuations may induce stress on the wafer, such as the stress caused by local conflicting regions of the wafer expanding or contracting, thereby resulting in the wafer buckling and no longer being substantially flush along a surface of the chuck. As a result, a gap may exist between the wafer and the chuck, which may negatively impact any thermal regulation attempted by the chuck.

For example, as described above, the chuck may be cooled via a fluid, which may transfer heat from the wafer through the chuck and into the fluid, thereby attempting to decrease the overall temperature of the wafer. However, if the wafer buckles due to significant heat fluctuations such as those described above, a gap may be present between the wafer and the chuck. As a result, the chuck and the fluid may no longer effectively cool the wafer due to a lack of direct contact between the wafer and the chuck. That is, heat from the wafer may ineffectively transfer through the gap (e.g., through an air gap or gaseous gap) into the chuck. Thus, overall heat transfer from the wafer to the fluid may be significantly impaired and may no longer be effective. However, the chuck assembly of the present teachings provides a solution to the aforementioned issues.

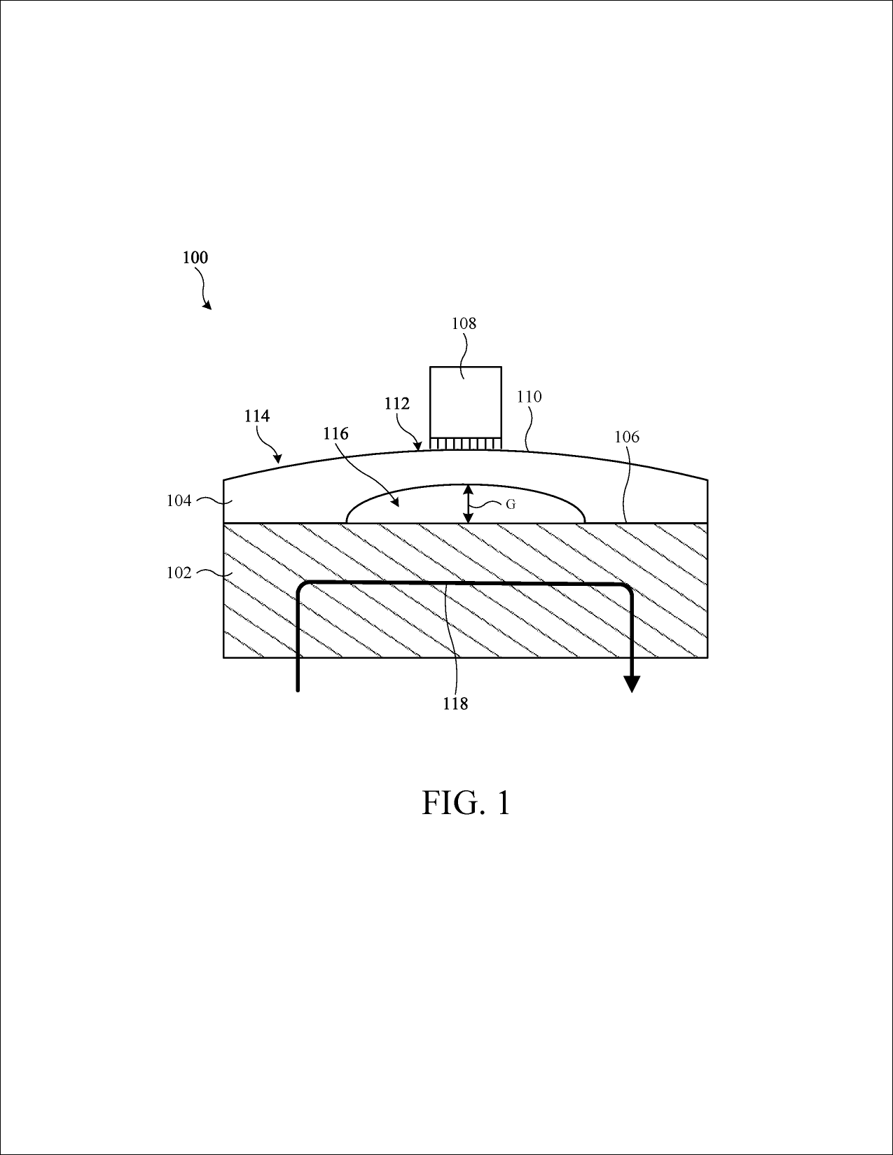

Turning now to the figures, FIG. 1 illustrates a cross-section of a configuration 100 of a chuck 102 supporting a wafer 104. The configuration 100 is included and described herein to better illustrate buckling of the wafer 104 and issues that may arise as a result of such buckling.

The chuck 102 may be configured to support the wafer 104 during manufacturing and/or testing. By way of example, as shown in FIG. 1, the wafer 104 may be disposed along, and supported by, a top surface 106 of the chuck 102 during testing. For example, the wafer 104 may be disposed on the top surface 106 of the chuck 102 such that a probe 108 may contact a top surface 110 of the wafer 104 to conduct testing (i.e., probing) of the wafer 104 to ensure proper functionality and/or quality of the wafer 104 and the electronics (e.g., integrated circuits, microchips, transistors, other microelectronic devices, etc.) therein. Additionally, it should also be noted that while the wafer 104 is described herein as a silicon wafer, the wafer 104 may be any suitable material. For example, the wafer 104 may be crystalline silicon, silicon carbide, gallium nitride, gallium arsenide, graphene transition metal dichalcogenides, germanium, diamond, other materials, or a combination thereof.

During testing, the probe 108 may be configured to align with specific portion of the wafer 104. For example, as shown in FIG. 1, the probe 108 may be configured to align with an inner region 112 of the wafer 104 and contact the top surface 110 of the wafer 104 within the inner region 112 of the wafer 104. That is, one or more electrical leads may contact the wafer 104 within the inner region 112 to conduct electrical testing, whereby the inner region 112 may be at least partially surround by an outer region 114. However, as discussed above, such testing may locally increase the temperature of the wafer 104 within the inner region 112, which may thereby increase the risk of damage to the wafer 104. For example, the local increase in temperature of the wafer 104 within the inner region 112 may cause the wafer 104 to buckle and form a gap 116 between the wafer 104 and the top surface 106 of the chuck 102.

As shown in FIG. 1, the gap 116 may be defined as a cavity formed between the wafer 104 and the top surface 106 of the chuck 102. The gap 116 may be filled with air or gas (e.g., helium, hydrogen), which may thereby decrease an overall area of contact between the wafer 104 and the chuck 102. That is, as a gap distance (G) between the wafer 104 and the top surface 106 of the chuck 102 increases, the effectiveness of thermal regulation (e.g., cooling) of the wafer 104 decreases. As a result, the thermal regulation (e.g., cooling) of the wafer 104, such as using a fluid 118 circulating through and/or around the chuck 102, may be difficult due to the poor thermal interface resistance caused by the gap 116 or may be entirely ineffective. Thus, the wafer 104 may not be properly thermally regulated (e.g., properly cooled), which may result in even further degradation to the wafer 104, thereby negatively impacting the performance of the wafer 104 (e.g., negatively impacting the performance of the electronics disposed on or within the wafer 104).

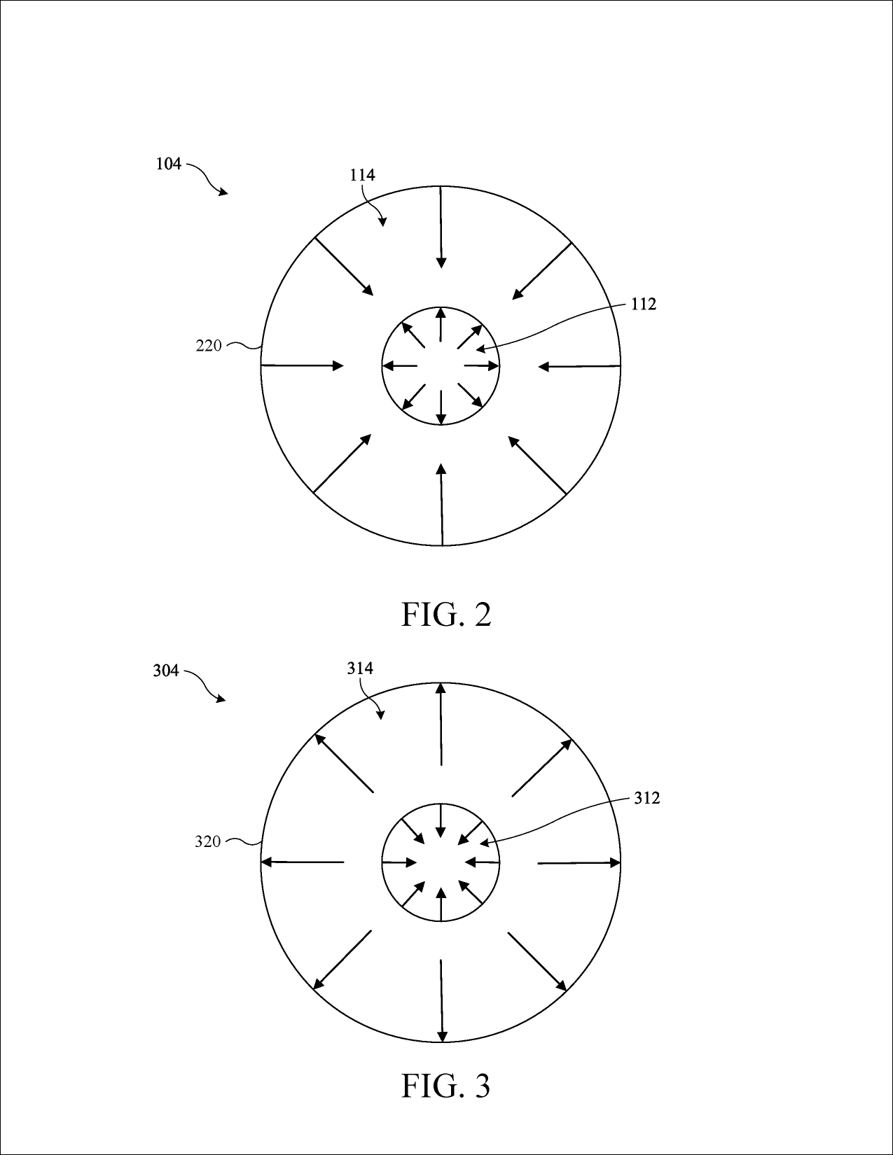

FIG. 2 illustrates a top-down view of the wafer 104 shown in the configuration 100 of FIG. 1 to illustrate how buckling of the wafer 104 may occur during testing of the wafer 104 (e.g., during probing of the wafer 104 by the probe 108). In the example shown in FIG. 1, the inner region 112 of the wafer 104 may be contacted by the probe 108, which may result in the inner region 112 increasing in temperature compared to the outer region 114. As a result of such a temperature increase, the inner region 112 may thermally expand relative to the outer region 114. That is, the inner region 112, which is hotter, may attempt to thermally expand outward towards the outer region 114 and towards an outer perimeter 220 of the wafer 104, as illustrated by the arrows located in the inner region 112 shown in FIG. 1. However, the outer region 114, which is colder, may not thermally expand similar to the inner region 112 or may even thermally contact toward the inner region 112, as illustrated by the arrows located in the outer region 114 shown in FIG. 1. This conflict in thermal expansion and contraction of the inner region 112 and the outer region 114, respectively, may result in buckling of the wafer 104, which may cause the gap 116 to form between the wafer 104 and the top surface 106 of the chuck 102. As a result, a thermal resistance between the wafer 104 and the chuck 102 may significantly increase (e.g., compared to before the wafer 104 buckles), which may thereby result in thermal regulation of the wafer 104 (e.g., via the fluid 118 shown in FIG. 1) being ineffective. Moreover, due to the rigorous testing of the wafer 104, the general cooling of the wafer 104 due to heat transfer from the wafer 104 to the fluid 118 may be unable to decrease the temperature of the inner region 112 sufficiently to prevent buckling of the wafer 104.

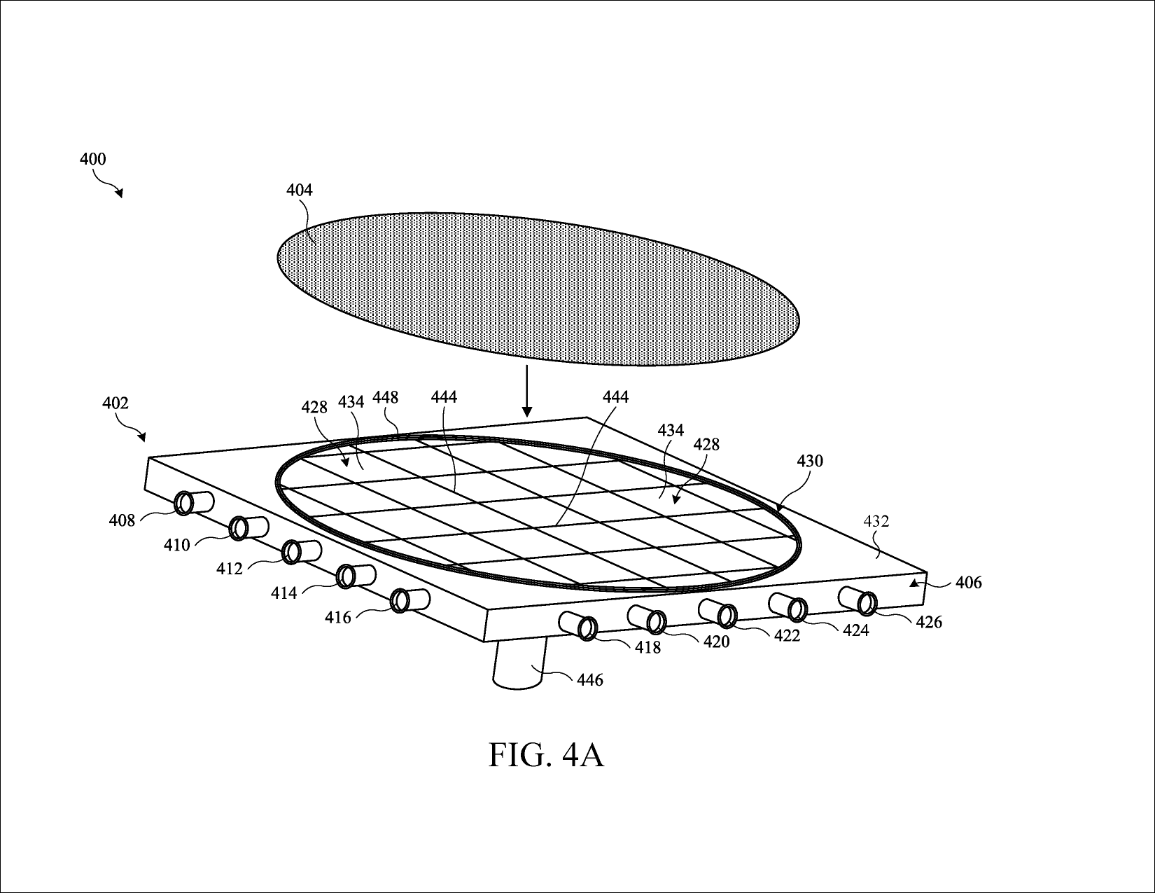

The present teachings seek to prevent buckling or other distortion of the wafer 104 caused by the thermal expansion and contraction shown in FIG. 2. For example, as shown in FIG. 3, the chuck assembly described herein may manipulate thermal expansion and contraction of a wafer, such as the wafer 304. The wafer 304 may be the same as or similar to the wafer 104. For example, the wafer 304 may also include an inner region 312 that may be at least partially surrounded by an outer region 314. While the wafer 304 is illustrated as being circular in shape, the wafer 304 may be any desired size and/or shape. For example, the wafer 304 may be rectangular, square, triangular, oval, or a combination thereof. Additionally, while the inner region 312 is illustrated as being centrally located on the wafer 304 and surrounded by the outer region 314, the wafer 304 may include any number of regions, which may be disposed anywhere along the wafer 304 relative to one another.

To combat buckling of the wafer 304, the chuck assembly, as described further below, may be configured to locally thermally regulate regions of the wafer 304. For example, the chuck assembly may be configured to locally thermally regulate the inner region 312 of the wafer 304, the outer region 314 of the wafer 304, or both. In the example shown in FIG. 3, the chuck assembly may be configured to thermally regulate the inner region 312 such that a temperature of the inner region 312 may be maintained at a colder temperature than a temperature of the outer region 314. That is, the inner region 312 may be colder (e.g., by about 5°C or more, about 10°C or more, about 20°C or more, or about 30°C or more) than the outer region 314, even if the inner region 312 is undergoing testing (e.g., probing) that may increase the temperature of the inner region 312 compared to the outer region 314 is unregulated. In other words, the inner region 312 may be colder than the outer region 314 with differences typically ranging from single-digit degrees Celsius to tens-of-degrees Celsius.

Based on maintaining the inner region 312 at a colder temperature compared to a temperature of the outer region 314, buckling of the wafer 304 may be minimized or even eliminated to optimize a contact area between the wafer 304 and the chuck assembly described below. In particular, as shown in FIG. 3, the inner region 312, which is colder, may maintain its shape or may attempt to thermally contract towards a center of the wafer 304, as illustrated by the arrows located in the inner region 312 shown in FIG. 3. However, the outer region 314, which is warmer, may thermally expand toward an outer perimeter 320 of the wafer 304, as illustrated by the arrows located in the outer region 314 shown in FIG. 3. As a result, the expansion of the outer region 314 and the contraction or thermal inactivity (e.g., no expansion or contraction) of the inner region 312 may maintain the wafer 304 under tension. That is, due to the inner region 312 being colder than the outer region 314, the wafer 304 may be pulled taught due to the aforementioned thermal expansion and contraction, thereby reducing or even eliminating buckling of the wafer 304.

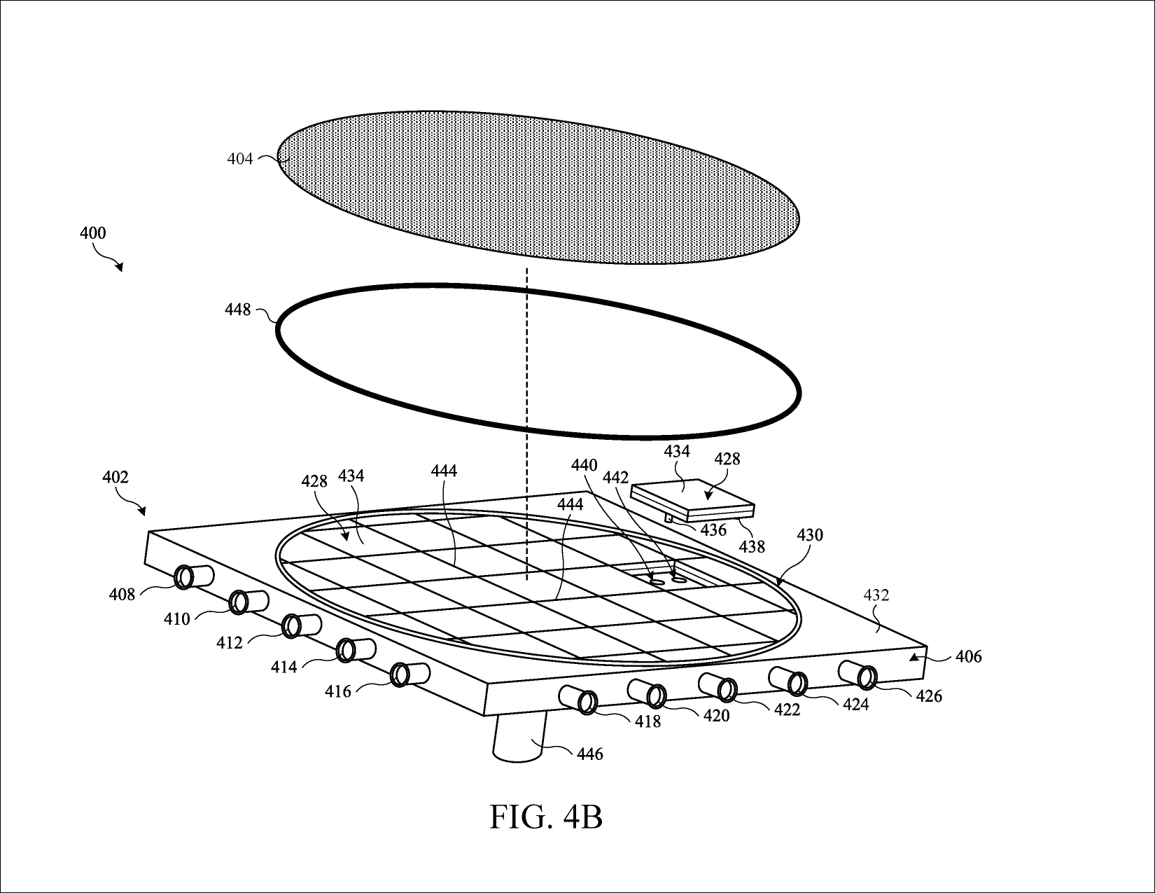

To better illustrate how localized thermal regulation is implemented as described above with respect to the wafer 304 shown in FIG. 3, FIGS. 4A and 4B will now be discussed in further detail. FIG. 4A illustrates a perspective view of a configuration 400 of a chuck assembly 402 supporting a wafer 404. FIG. 4B illustrates an exploded perspective view of the configuration 400 of the chuck assembly 402 shown in FIG. 4A.

The chuck assembly 402 may be configured to locally thermally regulate one or more regions (e.g., portions, segments, areas, etc.) of the wafer 404. For example, the wafer 404 may be the same as or similar to the wafer 104 shown in FIGS. 1 and 2 or the wafer 304 shown in FIG. 3, and the wafer 404 may include an inner region, an outer region, other regions, or a combination thereof. Thus, the chuck assembly 402 may be configured to thermally regulate (e.g., heat and/or cool) all or a portion of the regions of the wafer 404. That is, the chuck assembly 402 may selectively regulate a temperature of one or more desired portions of the wafer 404, such as those regions that may undergo testing (e.g., probing) and exhibit an increased temperature if left unmanaged. The one or more desired portions may be of various sizes, shapes, and placements on the wafer 404.

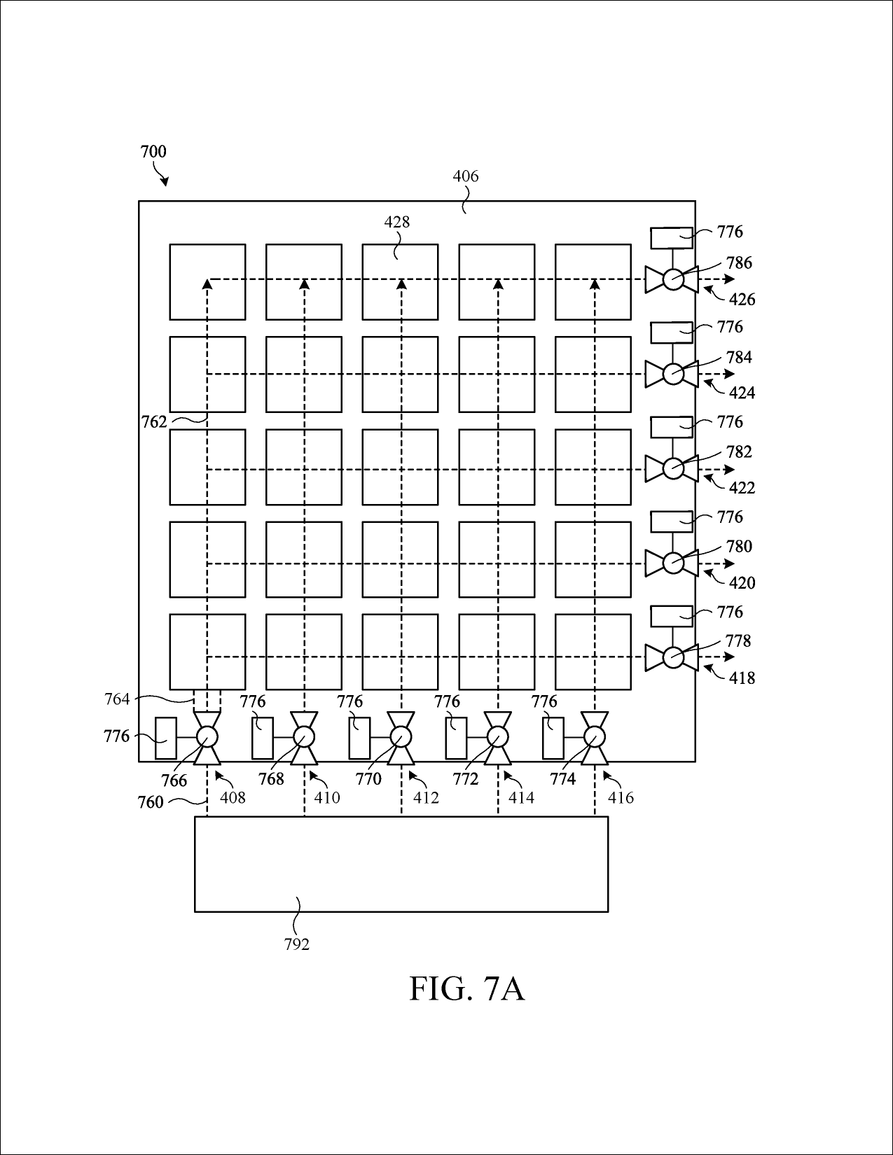

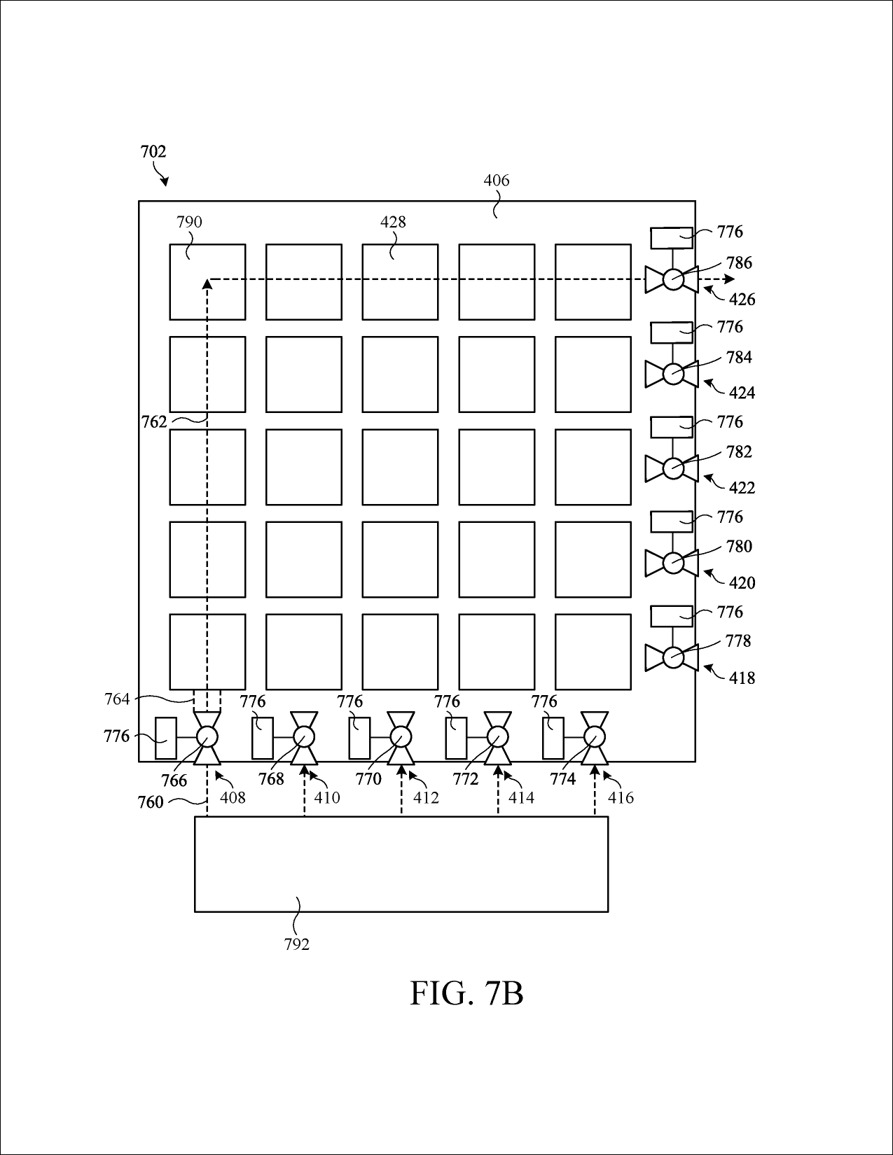

The chuck assembly 402 may include a manifold base 406 defining one or more channels therein (see, e.g., FIGS. 6-7B). The manifold base 406 may act as a housing and/or structural support of the chuck assembly 402. The manifold base 406 may also facilitate thermal regulation of the wafer 404 via the one or more channels therein. For example, the manifold base 406 may include inlet ports, such as inlet ports 408-416, that may be in fluid communication with the one or more channels of the manifold base 406. The inlet ports 408-416 may be described herein as a first inlet port 408, a second inlet port 410, a third inlet port 412, a fourth inlet port 414, and a fifth inlet port 416. The manifold base 406 may also include outlet ports, such as outlet ports 418-426, that may be in fluid communication with the one or more channels of the manifold base 406. The outlet ports 418-426 may be described herein as a first outlet port 418, a second outlet port 420, a third outlet port 422, a fourth outlet port 424, and a fifth outlet port 426.

The inlet ports 408-416 may be in fluid communication with the outlet ports 418-426 via the one or more channels of the manifold base 406. That is, a fluid (e.g., a coolant fluid) may enter the manifold base 406 (e.g., may enter one or more of the channels of the manifold base 406) via one or more of the inlet ports 408-416, flow through the manifold base 406 (e.g., flow through one or more of the channels of the manifold base 406), and exit the manifold base 406 (e.g., exit one or more of the channels of the manifold base 406) via one or more of the outlet ports 418-426.

The chuck assembly 402 may also include one or more cold plates, such as the cold plates 428. The cold plates 428 may be coupled to the manifold base 406 and configured to support the wafer 404. For example, the manifold base 406 may define a cutout 430 along a top surface 432 of the manifold base 406. The cold plates 428 may be positioned within the cutout 430 such that a top surface 434 of each of the cold plates 428 may be substantially coplanar with the top surface 432 of the manifold base 406. The top surface 434 of each of the cold plates 428 may also be substantially coplanar with one another. That is, each of the cold plates 428 may define a top surface 434 that is configured contact and support the wafer 404 for manufacturing and/or testing of the wafer 404. The cold plates 428 may thus form an overall substantially planar surface of the chuck assembly 402 such that the wafer 404 may be disposed along all or a portion of the cold plates 428 in a flush manner substantially free of any gaps between the cold plates 428 and the wafer 404. In some implementations, the cold plates 428 or the top surface 434 thereof may include contour or texture (e.g., a friction surface) to help maintain a position of the wafer 404 during manufacturing and/or testing of the wafer 404 and prevent unwanted slippage of the wafer 404.

Each of the cold plates 428 may be in fluid communication with the manifold base 406. For example, each of the cold plates 428 may define a cold plate channel (see, e.g., FIG. 6) that is in fluid communication with the channels of the manifold base 406. As shown in FIG. 4B, each of the cold plates 428 may include a cold plate inlet 436 and a cold plate outlet 438, whereby the fluid (e.g., the coolant fluid) may enter the cold plate channel of one of the cold plates 428 through the cold plate inlet 436 of that particular cold plate and may exit the cold plate channel through the cold plate outlet 438 of that particular cold plate. To facilitate fluid communication between each of the cold plates 428 and the manifold base 406 (e.g., fluid communication between the channels of the manifold base 406 and respective cold plate channels of the cold plates 428), the cold plate inlet 436 and/or the cold plate outlet 438 may be inserted into respective openings defined by the manifold base 406.

For example, FIG. 4B illustrates one of the cold plates 428 removed from the manifold base 406 for illustrative purposes. The manifold base 406 may define a first opening 440 and a second opening 442. The first opening 440 and the second opening 442 may be located within the cutout 430 and may align with the cold plate inlet 436 and the cold plate outlet 438, respectively, of the removed one of the cold plates 428. That is, when the removed one of the cold plates 428 is coupled to the manifold base 406, the cold plate inlet 436 may be received by the first opening 440 defined by the manifold base 406 and the cold plate outlet 438 may be received by the second opening 442 defined by the manifold base 406 such that the fluid (e.g., the coolant fluid) may flow from the one or more channels of the manifold base 406, into the cold plate channel via the cold plate inlet 436 (and the first opening 440), and exit the cold plate channel via the cold plate outlet 438 (and the second opening 442) to reenter the one or more channels of the manifold base 406. Thus, each of the cold plates 428 may facilitate localized thermal regulation (e.g., cooling) of the wafer 404 for a region of the wafer 404 localized on a particular one of the cold plates 428.

For example, a fluid (e.g., a coolant fluid) may enter the one or more channels of the manifold base 406 through one or more of the inlet ports 408-416, selectively flow through at least a portion of the cold plate channels (e.g., through at least a portion of the cold plates 428) to locally thermally regulate one or more regions of the wafer 404, and exit the one or more channels of the manifold base 406 through one or more of the outlet ports 418-426. As discussed further below, the inlet ports 408-416 and/or the outlet ports 418-426 may include or may be in fluid communication with valves to regulate a flow of the fluid through the inlet ports 408-416 and/or through the outlet ports 418-426 (see, e.g., FIGS. 7A-7B).

As described above, the chuck assembly 402 may thermally regulate the wafer 404 in a localized manner to selectively control a temperature of the wafer 404 in particular regions of the wafer 404, such as those regions being tested (e.g., probed). Additionally, to maintain a position of the wafer 404, the wafer 404 may be suctioned to the cold plates 428. To facilitate suctioning, the cold plates 428 may be spaced apart to form gaps 444 therebetween, as illustrated by the lines separating the cold plates 428 shown in FIGS. 4A and 4B. A size (e.g., width) of the gaps 444 is not particularly limited, and any number of the gaps 444 may exist based upon a desired level (e.g., power) of suction. The manifold base 406 may also include a vacuum port 446, and the gaps 444 may be in fluid communication with the vacuum port 446. Based on such a configuration, the wafer 404 may be suctioned to the cold plates 428 (e.g., to the top surface of the chuck assembly 402 defined by the respective top surfaces (e.g., the top surface 434) of the cold plates 428) by establishing an air flow path from the gaps 444 towards the vacuum port 446. That is, an impeller (e.g., a fan) may be coupled to or otherwise in fluid communication with the vacuum port 446 such that, when the impeller operates, air will be sucked from the gaps 444, through the vacuum port 446 and into the impeller to suction the wafer 404 to the cold plates 428.

Additionally, to improve suction of the wafer 404 to the cold plates 428, the chuck assembly 402 may include a seal 448. The seal 448 may be disposed along or around an outer perimeter of the cold plates 428 within the cutout 430 of the manifold base 406. For example, as shown in FIGS. 4A and 4B, the cutout 430 may be substantially circular and the seal 448 may disposed along the circular perimeter of the cutout 430 between the manifold base 406 and the cold plates 428 (e.g., between a wall of the cutout 430 and the outermost perimeter of cold plates 428). This a gap between the outermost perimeter of cold plates 428 and the manifold base 406 may be sealed by the seal 448. Additionally, the seal 448 may be an O-ring, gasket, or other sealing mechanism and is not particularly limited to the configuration shown in FIGS. 4A and 4B.

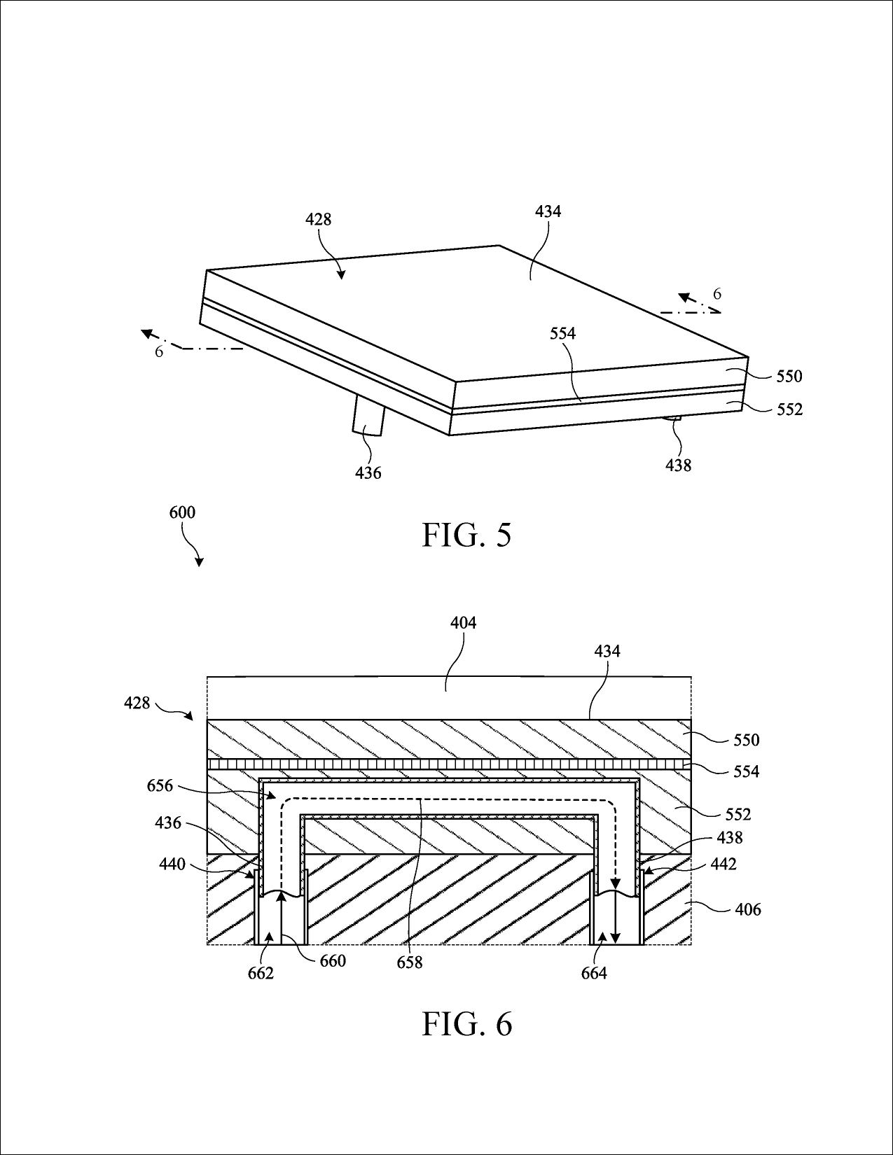

FIG. 5 illustrates a perspective view of an example of the cold plates 428 of the chuck assembly 402 shown in FIGS. 4A and 4B. For example, the exemplary cold plate shown in FIG. 5 may be the cold plate removed from the manifold base 406 in FIG. 4B. The description herein with respect to FIG. 5 may be applicable to any one of the cold plates 428 of the chuck assembly 402 shown in FIGS. 4A and 4B. For example, as shown in FIGS. 4A and 4B, the cold plates 428 may vary in size and/or shape to substantially fill the cutout 430 defined by the manifold base 406 (e.g., to form a circular shape to fit within the manifold base 406). Thus, some of the cold plates 428 may be smaller or larger compared to other ones of the cold plates 428. However, even though size and/or shape may differ between the cold plates 428, the configuration of the cold plates 428 may be substantially similar, as described below.

Each of the cold plates 428 may include a top layer 550, a bottom layer 552, and an intermediate layer 554. The top layer 550 may be configured to support the wafer (e.g., the wafer 404). That is, the top layer 550 may be or may include the top surface 434 of a respective one of the cold plates 428. As shown in FIG. 5, the top layer 550 may include the top surface 434, which may be substantially planar to support the wafer (e.g., the wafer 404).

The bottom layer 552 may couple the cold plates 428 to the manifold base 406 to establish fluid communication between the manifold base 406 and the cold plates 428. For example, as described above, the cold plates 428 may include a cold plate inlet 436 and a cold plate outlet 438. The cold plate inlet 436 may be received by the first opening 440 defined by the manifold base 406 and the cold plate outlet 438 may be received by the second opening 442 defined by the manifold base 406 to establish fluid communication between the cold plates 428 (e.g., a cold plate channel therein) and the manifold base 406. While a position of the cold plate inlet 436 and the cold plate outlet 438 is not particularly limited, the cold plate inlet 436 and the cold plate outlet 438 may be positioned to align with respective openings (e.g., the first opening 440 and the second opening 442) defined by the manifold base 406. For example, the cold plate inlet 436 and the cold plate outlet 438 may project from the bottom layer 552 of the cold plates 428.

As shown in FIG. 5, the intermediate layer 554 may be disposed between the top layer 550 and the bottom layer 552. The intermediate layer 554 may be configured to heat the top layer 550, the bottom layer 552, or both. For example, the intermediate layer 554 may be a conductive material or a thin-film heater embedded in the top layer 550 and/or the bottom layer 552. In an example, the intermediate layer 554 may be a thin-film heater that may be electrically connected to a power source (e.g., an external power source, such as a wall outer, or a battery) such that electrical current may transmit through the thin-film heater to locally heat the cold plates 428. Thus, the intermediate layer 554 may provide additional thermal regulation (e.g., heating) of the cold plates 428 along with thermal regulation of the cold plates 428 provided by the fluid flowing through the manifold base 406 and the cold plates 428. The power sourced by the power source may be conditioned, controlled, or modulated in some way. In a non-limiting example, a programmable DC power supply may be used to vary the supply voltage to the heater in response to a low-power digital or analog control signal.

The top layer 550 and the bottom layer 552 are not limited to any particular material. For example, the top layer 550 and/or the bottom layer 552 may be aluminum, copper, silver, stainless steel, copper alloys, other metals or metal alloys, or a combination thereof. In some implementations, the top layer 550 and/or the bottom layer 552 may also be a polymer or material other than a metal or metal allow. Additionally, the top layer 550 and the bottom layer 552 may be the same material or may be dissimilar materials (e.g., the top layer 550 is copper while the bottom layer 552 is aluminum).

Moreover, a thickness of the top layer 550 and a thickness of the bottom layer 552 are not particularly limited. For example, a thickness of the top layer 550 (e.g., as measured from the top surface 434 to the intermediate layer 554) may be less than a thickness of the bottom layer 552 (e.g., as measured from an outermost bottom surface of the bottom layer 552 that contacts the manifold base 406 to the intermediate layer 554), or vice versa. The thickness of the top layer 550 and/or the bottom layer 552 may be about 1 mm or more, about 2 mm or more, or about 3 mm or more. The thickness of the top layer 550 and/or the bottom layer 552 may be about 10 mm or less, about 5 mm or less, or about 4 mm or less. The thickness of the top layer 550 and/or the bottom layer 552 may be between 0.5 mm and 10 mm. Thus, the cold plates 428 may be configurable based upon a particular application and desired performance (e.g., desired thermal mass, desired thermal time constraints, etc.)

FIG. 6 illustrates cross-section 6-6 of the example of the cold plates 428 shown in FIG. 5. For illustrative purposes, FIG. 6 shows a configuration 600 of the example of the cold plates 428 supporting a portion of the wafer 404 shown in FIGS. 4A and 4B. The example of the cold plates 428 is also shown as being supported (e.g., received by) at least a portion of the manifold base 406.

As discussed above, the cold plates 428 may include the top layer 550, the bottom layer 552, and the intermediate layer 554 therebetween. A portion of the top layer 550, such as the top surface 434 of the cold plates 428, may support all or a portion of the wafer 404 during manufacturing and/or testing of the wafer 404. In addition to structural support of the wafer 404, the cold plates 428 – and the chuck assembly 402 as a whole – may also thermally regulate the wafer 404.

To facilitate such thermal regulation of the wafer 404 within a region of the wafer 404 disposed on the cold plates 428, the cold plates 428 may define a cold plate channel 656 that is in fluid communication with one or more channels defined by the manifold base 406. The cold plate inlet 436 and the cold plate outlet 438 may be part of, or otherwise in fluid communication with, the cold plate channel 656 such that the cold plate inlet 436 and the cold plate outlet 438 may act as an inlet and an outlet, respectively, of the cold plate channel 656.

For example, as shown in FIG. 6, the cold plate inlet 436 and the cold plate outlet 438 may project away from the bottom layer 552 of the cold plates 428 towards the first opening 440 and the second opening 442, respectively, of the manifold base 406. The cold plate inlet 436 may be at least partially inserted into the first opening 440 and the cold plate outlet 438 may be at least partially inserted into the second opening 442 such that fluid communication may be established between the manifold base 406 and the cold plate channel 656. In particular, a flow path 658 (as indicated by the arrows shown in FIG. 6) of a fluid, such as the fluid 660 may flow through a first channel 662 of the manifold base 406, enter the cold plate channel 656 through the cold plate inlet 436, flow through the cold plate channel 656, and exit the cold plate channel 656 through the cold plate outlet 438, at which point the fluid 660 may flow back into a second channel 664 of the manifold base 406 to continue circulation of the fluid 660. That is, the fluid 660 may flow through the manifold base 406, into the cold plates 428, and reenter the manifold base 406 to continue circulation of the fluid 660 through the chuck assembly 402.

The first channel 662, the second channel 664, and the cold plate channel 656 shown in FIG. 6 may have any geometry, cross-section, or shape. Additionally, the manifold base 406 and the cold plates 428 may define any number of desired channels therein. For example, the cold plates 428 may include or define winding micro-channels, such as those described in U.S. Patent No. 8,474,516, all of which is incorporated herein in its entirety for all purposes. Thus, the manifold base 406 and/or the cold plates 428 of chuck assembly 402 may be tuned for any desired manner of thermal regulation of the wafer 404. For example, the cold plate channel 656 may extend through at least one of the top layer 550, the bottom layer 552, or the intermediate layer 554. By way of example, as shown in FIG. 6, the cold plate channel 656 may extend through the bottom layer 552.

FIG. 7A illustrates a schematic view 700 of the chuck assembly 402 shown in FIGS. 4A, 4B, and 6 to illustrate a flow path 762 of a fluid, such as the fluid 760 (e.g., a coolant fluid), through the chuck assembly 402. As described above, the chuck assembly 402 may include the manifold base 406 and the cold plates 428 disposed in or otherwise coupled to the manifold base 406 to establish fluid communication between the manifold base 406 and the cold plates 428 (e.g., via the fluid communication shown in FIG. 6). The manifold base 406 may also include the inlet ports 408-416 and the outlet ports 418-426 such that the flow path 762 of the fluid 760, illustrated as dotted lines and arrows in FIG. 7A, may be regulated to selectively direct the fluid 760 toward a desired portion of the cold plates 428. That is the inlet ports 408-416 and/or the outlet ports 418-426 may direct the fluid 760 to locally thermally regulate a region of the wafer (e.g., the wafer 404) that is located on a particular one (or more) of the cold plates 428.

The inlet ports 408-416 may be configured to selectively regulate the fluid 760 from entering the one or more channels of the manifold base 406, such as a channel 764 defined by the manifold base 406 that is in fluid communication with the first inlet port 408, through the inlet ports 408-416. Additionally, the outlet ports 416-426 may be configured to selectively regulate the fluid 760 from exiting the one or more channels of the manifold base 406 (e.g., one or more channels similar to the channel 764) through the outlet ports 418-426. Thus, the inlet ports 408-416 and/or the outlet ports 418-426 may regulate the fluid 760 such that the fluid 760 selectively flows through at least a portion of the cold plates 428 to locally thermally regulate the region(s) of the wafer (e.g., the wafer 404) disposed on the portion of the cold plates 428.

To facilitate such regulation of the fluid 760, the inlet ports 408-416 may include or be in fluid communication with a respective inlet valve that regulates the fluid 760 from entering the one or more channels of the manifold base 406 through the inlet ports 408-416. For example, as shown in FIG. 7A, the inlet ports 408-416 may each be or include a respective one of the inlet valves 766-774 (e.g., the first inlet valve 766, the second inlet valve 768, the third inlet valve 770, the fourth inlet valve 772, and the fifth inlet valve 774). The inlet valves 766-774 may be any type of valve, such as a gate valve, a globe valve, a ball valve, a butterfly valve, a check valve, a needle valve, a pinch valve, a diaphragm valve, another type of valve, or a combination thereof. The inlet valves 766-774 may be controlled by a controller to regulate a flow rate of the fluid 760 traveling through a respective one of the inlet ports 408-416. For example, each of the inlet valves 766-774 may include, or may be in communication with, a controller 776, whereby the controller 776 of each of the inlet valves 766-774 may control a position of a respective one of the inlet valves 766-774. Thus, the flow rate of the fluid 760 into and through the inlet ports 408-416 may be regulated to increase, decrease, stop, or a combination thereof the flow rate of the fluid 760 into and through the inlet ports 408-416. For example, as shown in FIG. 7A, all of the inlet valves 766-774 are at least partially open such that the fluid 760 may flow from a reservoir 792 (e.g., another portion of the manifold base 406 and/or the chuck assembly 402, such as a tank, basin, storage compartment, etc.) into the manifold base 406 through all of the inlet ports 408-416.

Additionally, the outlet ports 418-424 may include or be in fluid communication with a respective outlet valve that regulates the fluid 760 from exiting the one or more channels (e.g., one or more channels similar to the channel 764) of the manifold base 406 through the outlet ports 418-424. For example, as shown in FIG. 7A, the outlet ports 418-424 may each be or include a respective one of the outlet valves 778-786 (e.g., the first outlet valve 778, the second outlet valve 780, the third outlet valve 782, the fourth outlet valve 784, and the fifth outlet valve 786). The outlet valves 778-786 may be any type of valve, such as a gate valve, a globe valve, a ball valve, a butterfly valve, a check valve, a needle valve, a pinch valve, a diaphragm valve, another type of valve, or a combination thereof. The outlet valves 778-786 may be controlled by a controller to regulate a flow rate of the fluid 760 traveling through a respective one of the outlet ports 418-424. For example, each of the outlet valves 778-786 may include, or may be in communication with, the controller 776, whereby the controller 776 of each of the outlet valves 778-786 may control a position of a respective one of the outlet valves 778-786. Thus, the flow rate of the fluid 760 into and through the outlet ports 418-424 may be regulated to increase, decrease, stop, or a combination thereof the flow rate of the fluid 760 into and through the outlet ports 418-424. For example, as shown in FIG. 7A, all of the outlet valves 766-774 are at least partially open such that the fluid 760 may flow from the manifold base 406 (e.g., the channels therein) out of all of the outlet ports 418-424. Thus, in the configuration shown in FIG. 7A, the fluid 760 is configured to at least partially flow through all of the cold plates 428 of the chuck assembly 402.

FIG. 7B illustrates another schematic view 702 of the chuck assembly 402 shown in FIGS. 4A, 4B, and FIG. 6 to illustrate another example of a flow path 762 of the fluid 760, illustrated as dashed lines and arrows in FIG. 7B. The schematic view 702 is the same configuration as the schematic view 700 shown in FIG. 7A. However, the schematic view 702 illustrates regulation of the fluid 760 to establish a different flow path of the fluid 760 through the chuck assembly 402 compared to the flow path shown in FIG. 7A.

In the configuration shown in FIG. 7B, a first inlet valve 766 may be open such that the fluid 760 may enter the manifold base 406 through the first inlet port 408, whereby the fluid 760 may flow through the channel 764 of the manifold base 406 and/or one or more additional channels of the manifold base 406. The remaining inlet valves 768-774 may be closed to prevent the fluid 760 from entering any of the inlet valves 410-416. Similarly, a fifth outlet valve 786 may be open such that the fluid 760 may exit the manifold base 406 through the fifth outlet port 426. The remaining outlet valves 778-786 may be closed to prevent the fluid 760 from exiting the manifold base 406 through any of the outlet valves 418-424. Thus, as shown in FIG. 7B, the fluid 760 may be regulated by the inlet valves 766-774 and the outlet valves 778-786 such that the fluid 760 may be selectively directed to a particular one of the cold plates 428, such as the cold plate 790, to locally thermally regulate a region or the wafer (e.g., the wafer 404) disposed on the cold plate 790. Thus, the inlet valves 766-774 and the outlet valves 778-786 may facilitate any desired flow path of the fluid 760 through the chuck assembly 402 to selectively thermally regulate any desired portion of the cold plates 428.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

Persons skilled in the art will understand that the various embodiments of the present disclosure and shown in the accompanying figures constitute non-limiting examples, and that additional components and features may be added to any of the embodiments discussed hereinabove without departing from the scope of the present disclosure. Additionally, persons skilled in the art will understand that the elements and features shown or described in connection with one embodiment may be combined with those of another embodiment without departing from the scope of the present disclosure to achieve any desired result and will appreciate further features and advantages of the presently disclosed subject matter based on the description provided. Variations, combinations, and/or modifications to any of the embodiments and/or features of the embodiments described herein that are within the abilities of a person having ordinary skill in the art are also within the scope of the present disclosure, as are alternative embodiments that may result from combining, integrating, and/or omitting features from any of the disclosed embodiments.

Use of the term “optionally” with respect to any element of a claim means that the element may be included or omitted, with both alternatives being within the scope of the claim. Additionally, use of broader terms such as “comprises,” “includes,” and “having” should be understood to provide support for narrower terms such as “consisting of,” “consisting essentially of,” and “comprised substantially of.” Accordingly, the scope of protection is not limited by the description set out above, but is defined by the claims that follow, and includes all equivalents of the subject matter of the claims.

In the preceding description, reference may be made to the spatial relationship between the various structures illustrated in the accompanying drawings, and to the spatial orientation of the structures. However, as will be recognized by those skilled in the art after a complete reading of this disclosure, the structures described herein may be positioned and oriented in any manner suitable for their intended purpose. Thus, the use of terms such as “above,” “below,” “upper,” “lower,” “inner,” “outer,” “left,” “right,” “upward,” “downward,” “inward,” “outward,” “horizontal,” “vertical,” etc., should be understood to describe a relative relationship between the structures and/or a spatial orientation of the structures. Those skilled in the art will also recognize that the use of such terms may be provided in the context of the illustrations provided by the corresponding figure(s).

Additionally, terms such as “approximately,” “generally,” “substantially,” and the like should be understood to allow for variations in any numerical range or concept with which they are associated and encompass variations on the order of 25% (e.g., to allow for manufacturing tolerances and/or deviations in design). For example, the term “generally parallel” should be understood as referring to configurations in with the pertinent components are oriented so as to define an angle therebetween that is equal to 180° ± 25% (e.g., an angle that lies within the range of (approximately) 135° to (approximately) 225°). The term “generally parallel” should thus be understood as referring to encompass configurations in which the pertinent components are arranged in parallel relation.

Although terms such as “first,” “second,” “third,” etc., may be used herein to describe various operations, elements, components, regions, and/or sections, these operations, elements, components, regions, and/or sections should not be limited by the use of these terms in that these terms are used to distinguish one operation, element, component, region, or section from another. Thus, unless expressly stated otherwise, a first operation, element, component, region, or section could be termed a second operation, element, component, region, or section without departing from the scope of the present disclosure.

Each and every claim is incorporated as further disclosure into the specification and represents embodiments of the present disclosure. Also, the phrases “at least one of A, B, and C” and “A and/or B and/or C” should each be interpreted to include only A, only B, only C, or any combination of A, B, and C.

What is claimed is:

1. A chuck assembly, comprising:
a manifold base defining one or more channels therein, wherein the manifold base includes:
inlet ports in fluid communication with the one or more channels, and
outlet ports in fluid communication with the one or more channels; and
cold plates coupled to the manifold base and configured to support a wafer, wherein each cold plate defines a cold plate channel that is in fluid communication with the one or more channels of the manifold base,
wherein a fluid is configured to enter the one or more channels of the manifold base through the inlet ports, selectively flow through at least a portion of the cold plate channels to locally thermally regulate a region of the wafer, and exit the one or more channels of the manifold base through the outlet ports.

2. The chuck assembly of claim 1, wherein the inlet ports are configured to selectively regulate the fluid from entering the one or more channels of the manifold base through the inlet ports and the outlet ports are configured to selectively regulate the fluid from exiting the one or more channels of the manifold base through the outlet ports such that the fluid selectively flows through at least the portion of the cold plate channels to locally thermally regulate the region of the wafer.

3. The chuck assembly of claim 2, wherein each of the inlet ports includes or is in fluid communication with a respective inlet valve that regulates the fluid from entering the one or more channels of the manifold base through the inlet ports.

4. The chuck assembly of claim 2, wherein each of the outlet ports includes or is in fluid communication with a respective outlet valve that regulates the fluid from exiting the one or more channels of the manifold base through the outlet ports.

5. The chuck assembly of claim 1, wherein the manifold base further defines a cutout and the cold plates are positioned within the cutout.

6. The chuck assembly of claim 5, wherein each of the cold plates define a top surface that is configured to contact and support the wafer, and wherein the top surfaces of the cold plates are substantially coplanar.

7. The chuck assembly of claim 1, wherein each of the cold plates includes:
a top layer that is configured to support the wafer;
a bottom layer; and
an intermediate layer disposed between the top layer and the bottom layer, wherein the intermediate layer is configured to heat the top layer, the bottom layer, or both.

8. The chuck assembly of claim 1, wherein each of the cold plates includes a cold plate inlet and a cold plate outlet, and wherein the fluid is configured to enter the cold plate channel through the cold plate inlet and exit the cold plate channel through the cold plate outlet.

9. The chuck assembly of claim 8, wherein the cold plate inlet is received by a first opening defined by the manifold base and the cold plate outlet is received by a second opening defined by the manifold base such that the fluid may flow from the one or more channels of the manifold base, into the cold plate channel, and exit the cold plate channel to reenter the one or more channels of the manifold base.

10. The chuck assembly of claim 1, wherein the manifold base further includes a vacuum port, the cold plates are spaced apart to form gaps therebetween, and the gaps are in fluid communication with the vacuum port.

11. The chuck assembly of claim 10, wherein the wafer is configured to be suctioned to the cold plates by establishing an air flow path from the gaps towards the vacuum port.

12. A chuck assembly, comprising:
a manifold base that includes:
an inlet port, and
an outlet port; and
a cold plate disposed on the manifold base, in fluid communication with the manifold base, and configured to support a wafer disposed on a top surface of the cold plate, wherein the cold plate includes:
a top layer that includes the top surface of the cold plate,
a bottom layer that couples the cold plate to the manifold base and establishes fluid communication between the manifold base and the cold plate, and
an intermediate layer disposed between the top layer and the bottom layer,
wherein a fluid is configured to thermally regulate the wafer, and the fluid is configured to enter the manifold base through the inlet port, flow through the cold plate, reentering the manifold base, and exit the manifold base through the outlet port.

13. The chuck assembly of claim 12, wherein the cold plate defines a cold plate channel and the manifold base defines a channel, and wherein the cold plate channel is in fluid communication with the channel of the manifold base.

14. The chuck assembly of claim 13, wherein the cold plate channel extends through at least one of the top layer, the bottom layer, or the intermediate layer.

15. The chuck assembly of claim 13, wherein the cold plate includes a cold plate inlet that is in fluid communication with the cold plate channel and a cold plate outlet that is in fluid communication with the cold plate channel, and wherein the cold plate inlet and the cold plate outlet are received by respective openings defined by the manifold base to establish fluid communication between the manifold base and the cold plate.

16. The chuck assembly of claim 15, wherein the cold plate inlet projects from the bottom layer and the cold plate outlet projects from the bottom layer.

17. The chuck assembly of claim 12, wherein the intermediate layer is configured to heat the top layer, the bottom layer, or both.

18. The chuck assembly of claim 12, wherein the top surface of the cold plate is coplanar with a top surface of the manifold base.

19. The chuck assembly of claim 12, wherein the inlet port includes an inlet valve that is configured to regulate the fluid entering the manifold base through the inlet port and the outlet port includes an outlet valve that is configured to regulate the fluid exiting the manifold base through the outlet port.

20. A chuck assembly, comprising:
a manifold base defining one or more channels therein, wherein the manifold base includes:
inlet ports that are configured to regulate a fluid entering the one or more channels of the manifold base, and
outlet ports that are configured to regulate a fluid exiting the one or more channels of the manifold base; and
cold plates disposed in a cutout defined by the manifold base to form a support surface of the chuck assembly that is configured to support a wafer, wherein the cold plates are selectively in fluid communication with the manifold base based upon regulation of the fluid by the inlet ports, the outlet ports, or both to locally thermally regulate a region of the wafer.
